(19) United States
(12) Patent Application Publication
(10) Pub. No.: US 2002/0058188 A1
(43) Pub. Date: May 16, 2002

(54) Method for rescuing levenson phase shift mask from abnormal difference in transmittance and phase difference between phase shifter and non-phase shifter

(75) Inventors: Haruo Iwasaki, Tokyo (JP); Shinji Ishida, Tokyo (JP)

Correspondence Address: SUGHRUE, MION, ZINN, MACPEAK & SEAS, 2100 Pennsylvania Avenue, N.W., Washington, DC, 20037, US

(73) Assignee: NEC CORPORATION

(21) Appl. No.: 09/987,401

(22) Filed: Nov. 14, 2001

(30) Foreign Application Priority Data
Nov. 16, 2000 (JP) 2000-350317

(51) Int. Cl. G03F 9/00; G06K 9/00; G03C 5/00; G06F 17/50

(52) U.S. Cl. 430/5; 430/322; 382/144; 716/21

(57) ABSTRACT

A Levenson phase shift mask has a phase shifter implemented by thin transparent portions and a non-phase shifter implemented by thick transparent portions, and the thin transparent portions are to be equal in transmittance to and 180 degrees different in phase from the thick transparent portions, wherein a dispersion of light intensity in optical images of the phase shifter and the non-phase shifter obtained by a CCD camera is analyzed to see whether or not the abnormal difference in transmittance and the abnormal phase difference take place, if the abnormal difference in transmittance or the abnormal phase difference takes place, the thin/thick transparent portions are reshaped so as to repair the Levenson phase shift mask.

### FIELD OF THE INVENTION

This invention relates to a photo-lithography and, more particularly, to a method for repairing a Levenson phase shift mask.

### DESCRIPTION OF THE RELATED ART

In a semiconductor device fabrication process, various mask patterns are transferred from photo masks to photo resist layers. Photo masks used in a reduction projection aligner is usually called as “reticle”. However, reticles are hereinbelow referred to as “photo mask”. In other words, words “photo mask” includes the reticles.

A Levenson phase shift mask is a typical example of the photo mask used in a reduction projection aligner, and is described by Levenson et al. in IEEE ED-29, page 1828, 1982. It is known that the Levenson phase shift mask enhances the resolution. A Levenson phase shift mask has a relatively thin portion serving as a phase shifter and a relatively thick portion serving as a non-phase shifter. The phase shifter makes the transmitted light 180 degrees different from the light transmitted through the non-phase shifter. As a result, the transmitted light exhibits a dispersion of light intensity sharply peaked, and a high resolution is achieved by virtue of the dispersion of light intensity.

FIGS. 1A to 1E shows a process for producing the Levenson phase shift mask. The prior art process starts with preparation of a transparent substrate 101. A chromium layer 104 is patterned on the upper surface of the transparent substrate 101. The chromium layer 104 has openings, and permits light to pass through the openings. Photo resist is spread over the upper surface of the transparent substrate 101, and the chromium layer 104 is covered with a photo resist layer 105. A pattern image for the phase shifter is transferred to the photo resist layer 105, and a latent image is produced in the photo resist layer 105 as shown in FIG. 1A.

The latent image is developed so that the photo resist layer 105 is partially removed from the transparent substrate 101 and the chromium layer 104. A part of the transparent substrate 101 is exposed to the hollow space formed in the photo resist layer 105.

Using the patterned photo resist layer, the transparent substrate 101 is selectively etched by using a dry etching technique, and recesses 102 are formed in the transparent substrate as shown in FIG. 1C. The recesses 102 serve as a phase shifter.

The patterned photo resist layer is stripped off, and an area assigned to the non-phase shifter 103 is exposed as shown in FIG. 1D. The transparent substrate 101 is subjected to a wet etching. The wet etchant deepens the recesses 102 or the phase shifter, and shallow recesses 103 are formed in another part of the transparent substrate 101 assigned to the non-phase shifter as shown in FIG. 1E. Thus, the deep recesses 102 and the shallow recesses 103 are formed in the transparent substrate 101. In other words, the phase shifter is implemented by the relatively thin portions, and the non-phase shifter 103 is implemented by the relatively thick portions.

The deep recesses 102 are alternated with the shallow recesses 103 as shown in FIG. 2, and each of the recesses 102/103 occupies a square area of 0.8 micron by 0.8 micron or more than 0.8 micron by more than 0.8 micron on the photo mask. In a pattern transfer, light is transmitted through the deep and shallow recesses 102/103, i.e., the phase shifter and the non-phase shifter. The deep recesses 102 shift the rays passing therethrough by 180 degrees with respect to the rays passing through the shallow recesses 103. As a result, sharp robes of light intensity take place, and results in a high resolution. Assuming now a virtual line crosses the deep recesses 102 and the shallow recesses 103 on the prior art Levenson phase shift mask, the light intensity is varied as shown in FIG. 3A. The sharp robes are surely observed. FIG. 3B shows the counter map taken along the dot-and-dash line of FIG. 3A. Thus, the Levenson phase shift mask is desirable to produce a clear latent image in a photo resist layer. Especially, patterns to be formed on and over a semiconductor substrate are getting finer and finer, and the proximity effect becomes serious. In this situation, the Levenson phase shift mask is preferable to clearly produce a fine pattern.

However, a problem is encountered in the prior art Levenson phase shift mask in abnormal difference in transmittance and abnormal phase difference. The abnormal difference in transmittance is causative of robes different in height as shown in FIG. 4A. The relatively high robes are representative of the light intensity of the rays passing through the shallow recesses 103, and the relatively low robes represent the light intensity of the rays passing through the deep recesses 102. The counter map is shown in FIG. 4B. On the other hand, the abnormal phase difference is the phenomenon where the rays passing through the deep recesses 102 are not exactly different in phase from the rays passing through the shallow recesses 103 by 180 degrees. The abnormal phase difference makes the robes obtuse, and, accordingly, the latent image unclear.

If the difference in transmittance and/or the phase difference takes place in the Levenson phase shift mask, the manufacturer checks the Levenson phase shift mask to see whether or not the difference in transmittance and/or the phase difference is abnormal. When the manufacturer decides the difference in transmittance and/or the phase difference to be abnormal, the manufacturer is to repair the Levenson phase shift mask.

A prior art repairing method is disclosed in Japanese Patent Application laid-open No. 11-218900. The prior art repairing method is applied to the standard photo masks. The prior art method includes two steps. A simulation is carried out in the first step, and the photo mask is corrected on the basis of the result of the simulation. In the simulation step, a latent image to be transferred from the mask pattern is simulated through optical analysis on the mask pattern to be produced on the basis of a designed pattern. If the latent image is to be rejected, the manufacturer proceeds to the next step, and repairs the photo mask. The prior art repairing method aims at the standard photo masks. In other words, the optical analysis is carried out on the assumption that the photo mask has a transparent pattern two dimensionally defined by a photo-shield layer. However, the Levenson phase shift mask has the three- dimensional transparent pattern, i.e., the transparent pattern consists of the phase shifter and the non-phase shifter. When the prior art repairing method is applied to the Levenson phase shift mask, the latent image is inaccurately simulated through the first step, and the result of the simulation is less reliable.

### SUMMARY OF THE INVENTION

It is therefore an important object of the present invention to provide a method for repairing a Levenson phase shift mask through which the Levenson phase shift mask is accurately evaluated within a short time period.

In accordance with one aspect of the present invention, there is provided a method for repairing a photo mask having a photo shield portion and plural transparent portions different in three-dimensional configuration from one another, comprising the steps of (a) radiating the photo mask with a light so as to obtain optical images each representative of the plural transparent portions at plural defocusing points, respectively, (b) analyzing the optical images to see whether or not at least one optical property of the plural transparent portions is adjusted to a target value on the basis of a difference in measurement between the plural transparent portions on the optical images, and (c) selectively reshaping the plural transparent portions for changing the three dimensional configurations thereof for adjusting the at least one optical property to the target value when the answer at the step (b) is given negative.

### BRIEF DESCRIPTION OF THE DRAWINGS

The features and advantages of the repairing method will be more clearly understood from the following description taken in conjunction with the accompanying drawings in which:

FIGS. 1A to 1E are cross sectional views showing the prior art process for producing the Levenson phase shift mask;

FIG. 2 is a plane view showing the arrangement of the recesses of the prior art Levenson phase shift mask;

FIG. 3A is a graph showing the dispersion of light intensity along the virtual line;

FIG. 3B is a counter map showing the dispersion of light intensity on the prior art Levenson phase shift mask;

FIG. 4A is a graph showing the dispersion of light intensity when the abnormal difference in transmittance takes place;

FIG. 4B is a counter map showing the dispersion of light intensity when the abnormal difference in transmittance takes place;

FIG. 5 is a schematic view showing the arrangement of component parts of a mask simulator used in a repairing method according to the present invention;

FIG. 6 is a cross sectional view showing the structure of a single trench Levenson phase shift mask;

FIG. 7 is a flowchart showing a method for repairing a Levenson phase shift mask according to the present invention;

FIG. 8 is a graph showing a relation between measurements in an optical image of a device pattern and the amount of defocus on condition that neither abnormal difference in transmittance nor abnormal phase difference does not take place;

FIG. 9 is a graph showing a relation between measurements in the optical image of a device pattern and the amount of defocus on condition that the abnormal difference in transmittance takes place;

FIG. 10 is a graph showing a relation between measurements in the optical image of the device pattern and the amount of defocus on condition that the abnormal phase difference takes place;

FIG. 11 is a cross sectional view showing a repairing work for rescuing a Levenson phase shift mask from the abnormal difference in transmittance;

FIG. 12 is a cross sectional view showing a repairing work for rescuing a Levenson phase shift mask from the abnormal phase difference;

FIGS. 13A to 13L are cross sectional views showing a process for reproducing a single trench Levenson phase shift mask;

FIGS. 14A to 14D are cross sectional views showing a repairing work after an investigation;

FIGS. 15A to 15F are cross sectional views showing a process for reproducing a single trench Levenson phase shift mask;

FIGS. 16A and 16B are plane views showing the thin transparent portions and thick transparent portions laid on different patterns;

FIGS. 17A and 17B are plane views showing a pattern image to be transferred to a photo resist layer and a pattern of a standard single trench Levenson phase shift mask;

FIG. 18 is a graph showing a relation between the amount of setback and the difference in measurement due to a difference in transmittance at defocus point of zero;

FIG. 19 is a graph showing a relation between the increment of depth and the difference in measurement due to a phase difference;

FIG. 20 is a cross sectional view showing the structure of a dual- trench Levenson phase shift mask;

FIG. 21 is a graph showing measurements in an optical image of a device pattern on a non-defective dual trench Levenson phase shift mask in terms of the amount of defocus;

FIG. 22 is a graph showing measurements in an optical image of a device pattern on a defective dual trench Levenson phase shift mask due to the abnormal difference in transmittance in terms of the amount of defocus;

FIG. 23 is a graph showing measurements in an optical image of a device pattern on a defective dual trench Levenson phase shift mask due to the abnormal phase difference in terms of the amount of defocus;

FIG. 24 is a cross sectional view showing a repairing work on a defective dual trench Levenson phase shift mask due to the abnormal difference in transmittance;

FIG. 25 is a cross sectional view showing a repairing work on a defective dual trench Levenson phase shift mask due to the abnormal phase difference;

FIGS. 26A to 26H are cross sectional views showing a process for producing a dual trench Levenson phase shift mask;

FIGS. 27A to 27D are cross sectional views showing a repairing work for rescuing the dual trench Levenson phase shift mask from the abnormal phase difference;

FIG. 28 is a cross sectional view showing a repairing work for rescuing the dual trench Levenson phase shift mask from the abnormal difference in transmittance;

FIG. 29 is a graph showing a relation between the difference in measurement on an optical image of the dual trench Levenson phase shift mask due to the difference in transmittance and a dual trench depth;

FIG. 30 is a graph showing a relation between the difference in measurement on an optical image of the dual trench Levenson phase shift mask due to the phase difference and a difference in depth between deep trenches and shallow trenches;

FIG. 31 is a plane view showing a device pattern of a Levenson phase shift mask before the repairing work and an optical image on a CCD camera;

FIG. 32 is a plane view showing a preliminary pattern correcting work on the device pattern;

FIG. 33 is a plane view showing an optical image of the device pattern after the preliminary pattern correcting work;

FIG. 34 is a plane view showing a device pattern of another Levenson phase shift mask and an optical image thereof before the preliminary pattern correcting work;

FIG. 35 is a plane view showing the preliminary pattern correcting work on the device pattern; and

FIG. 36 is a plane view showing the optical image after the preliminary pattern correcting work.

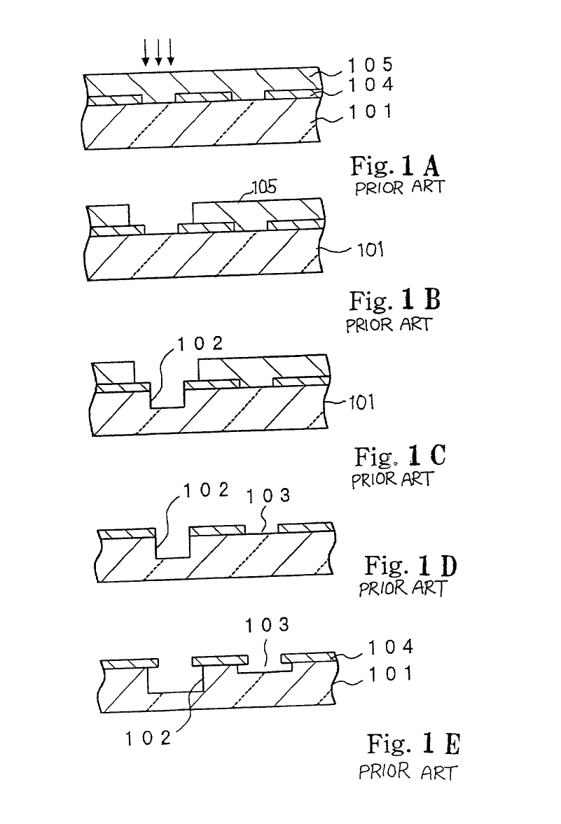

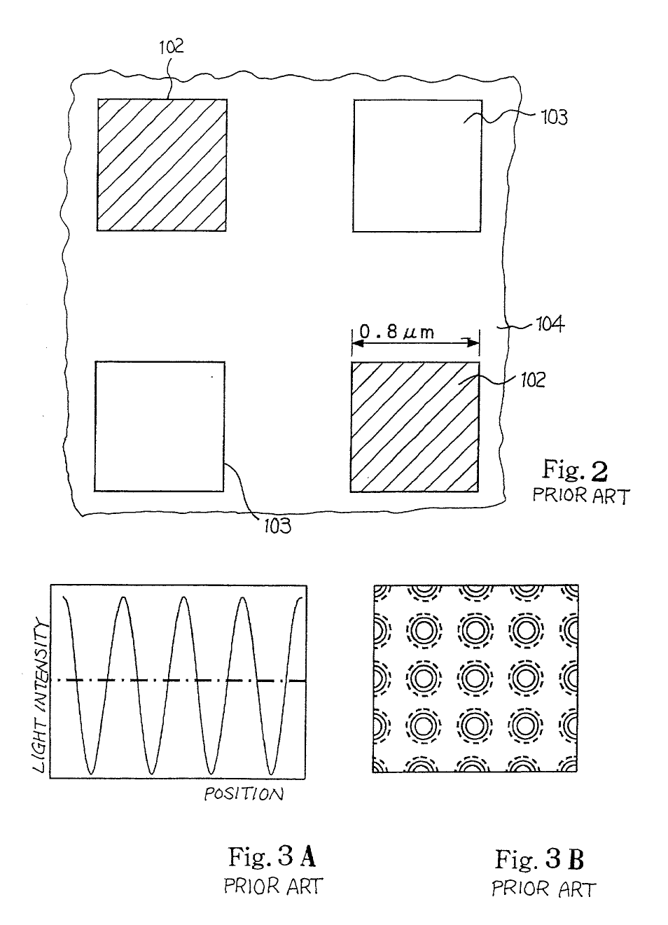

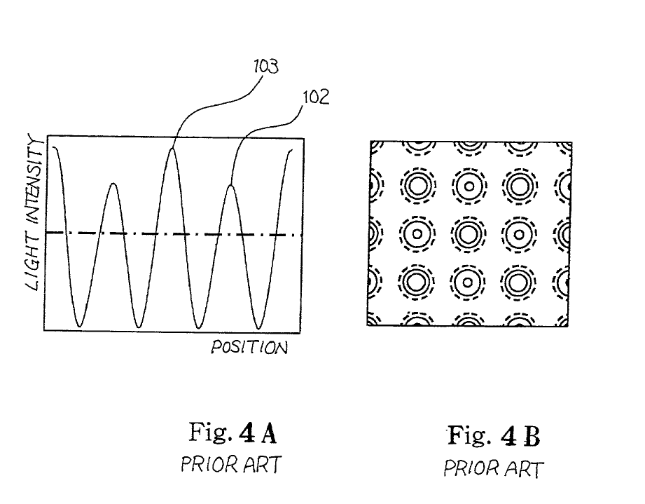

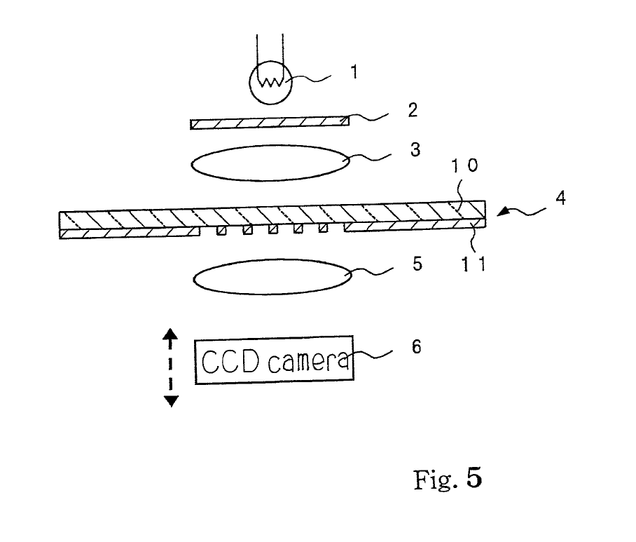

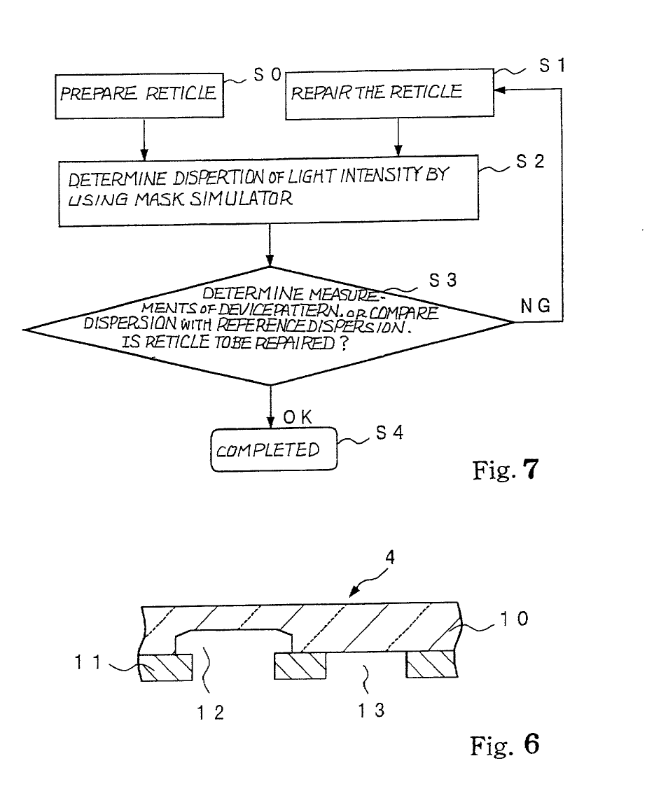

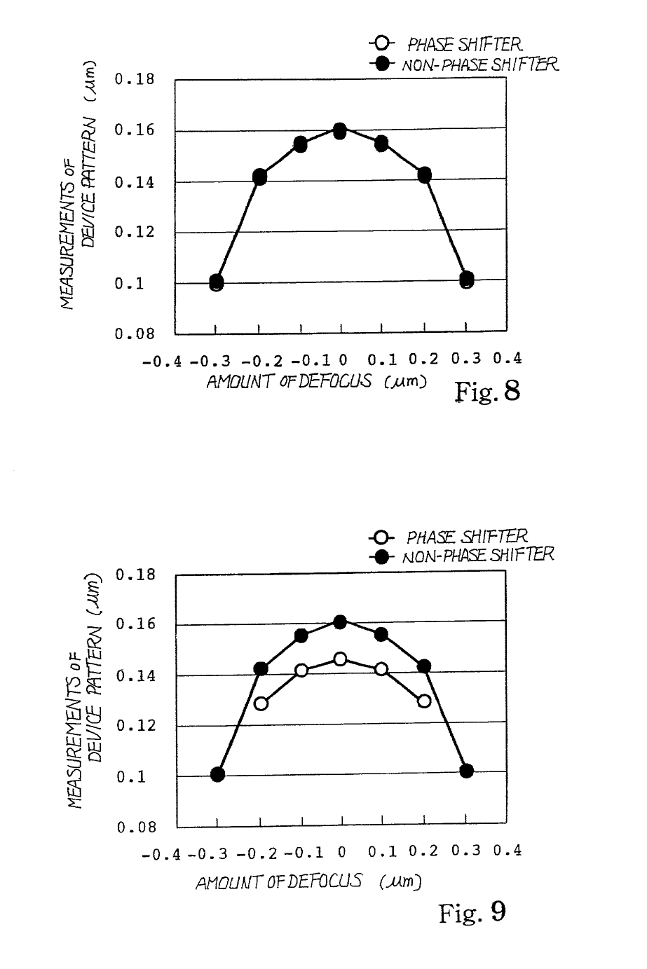

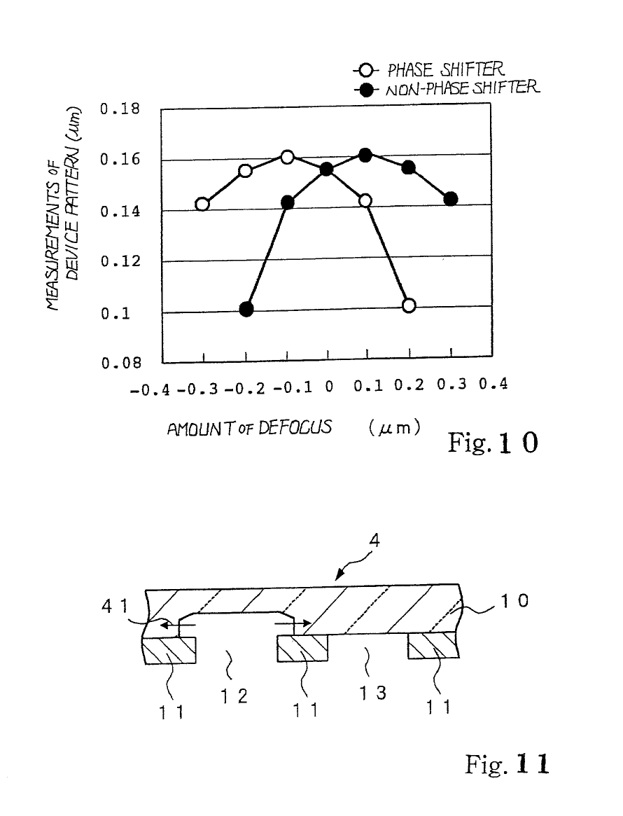

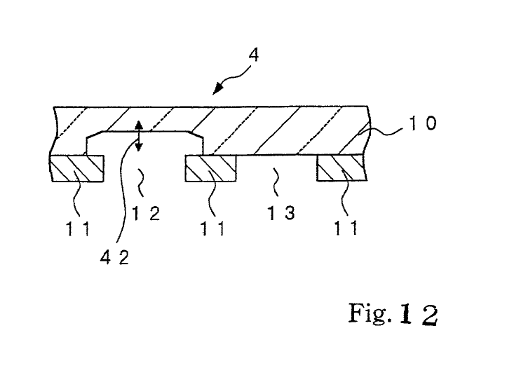

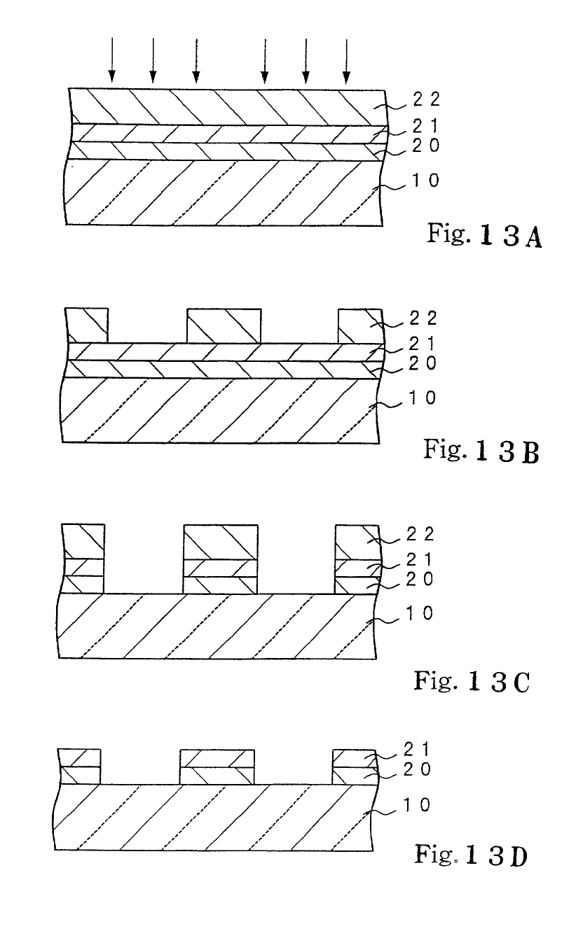

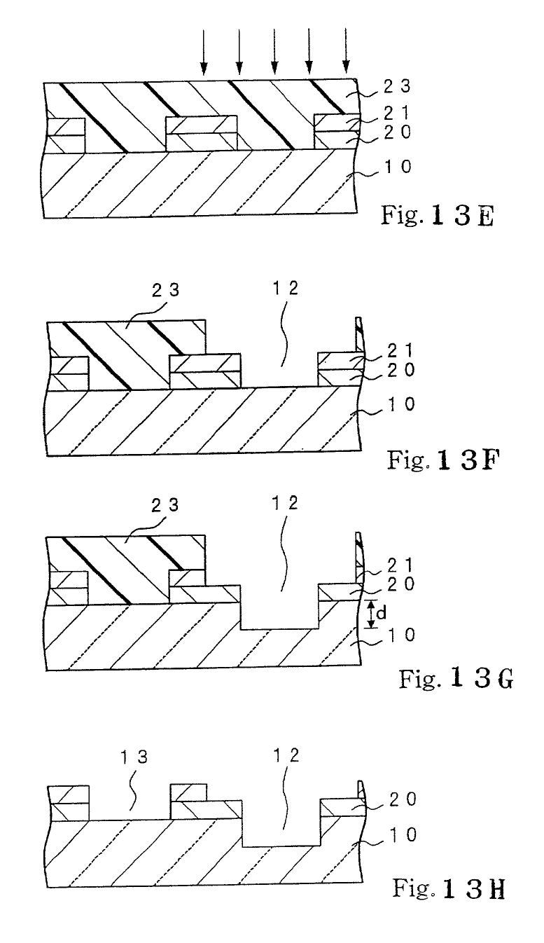

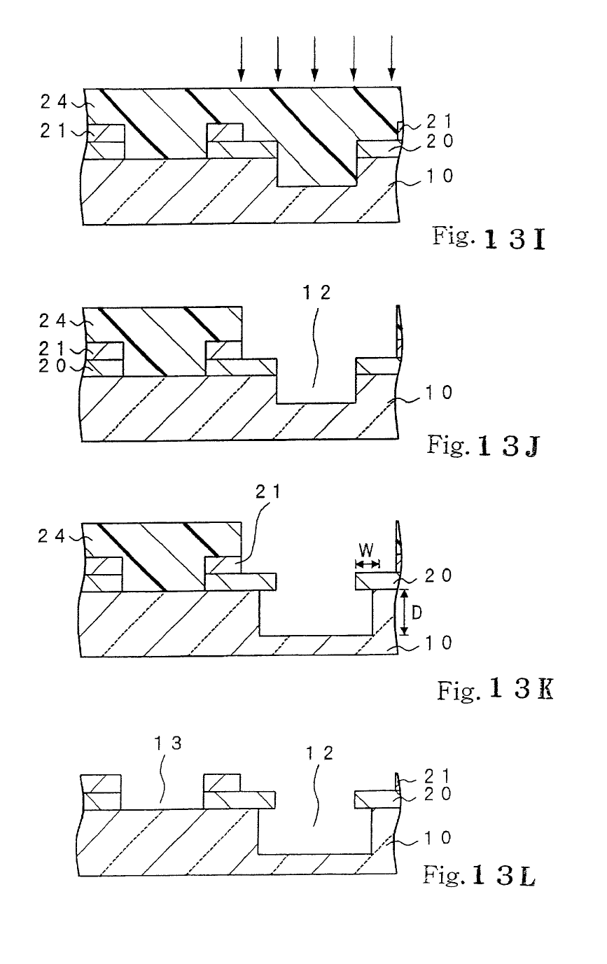

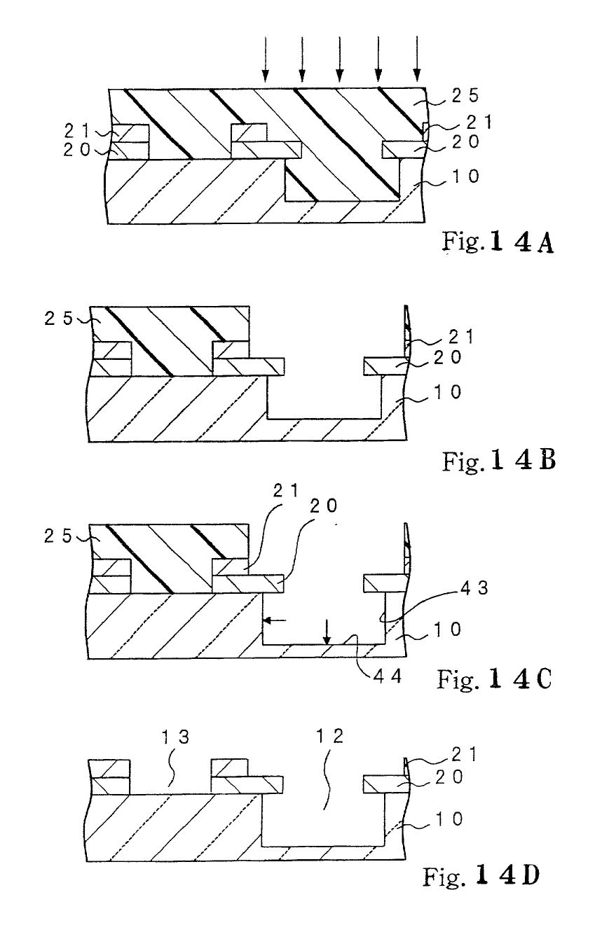

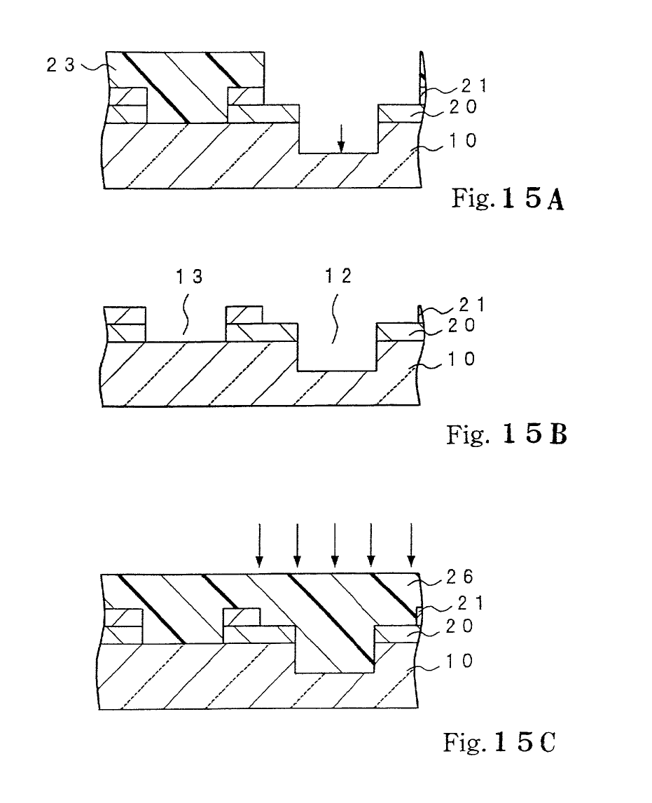

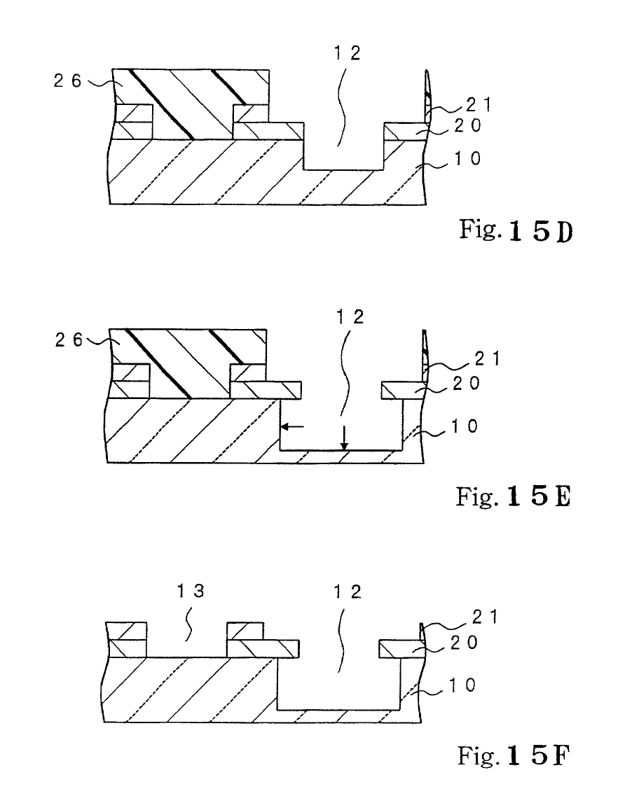

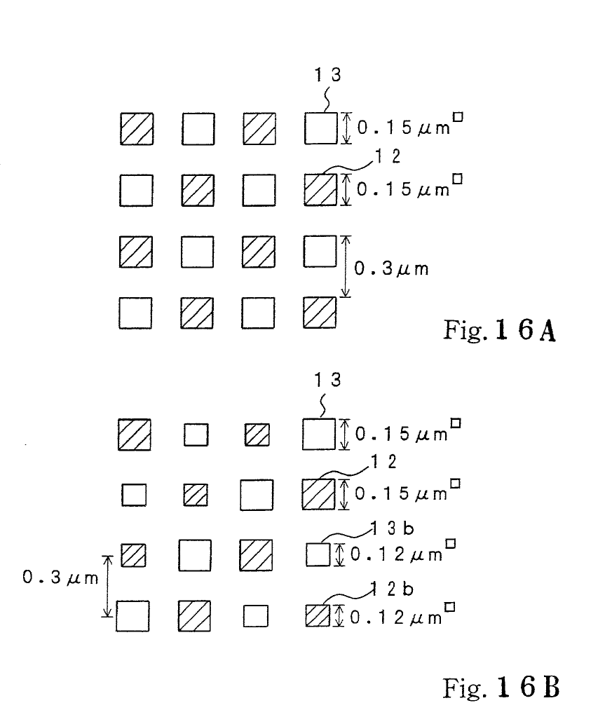

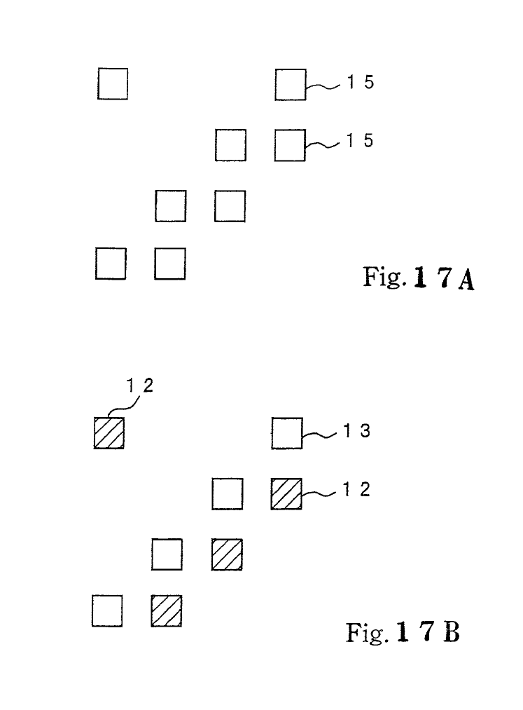

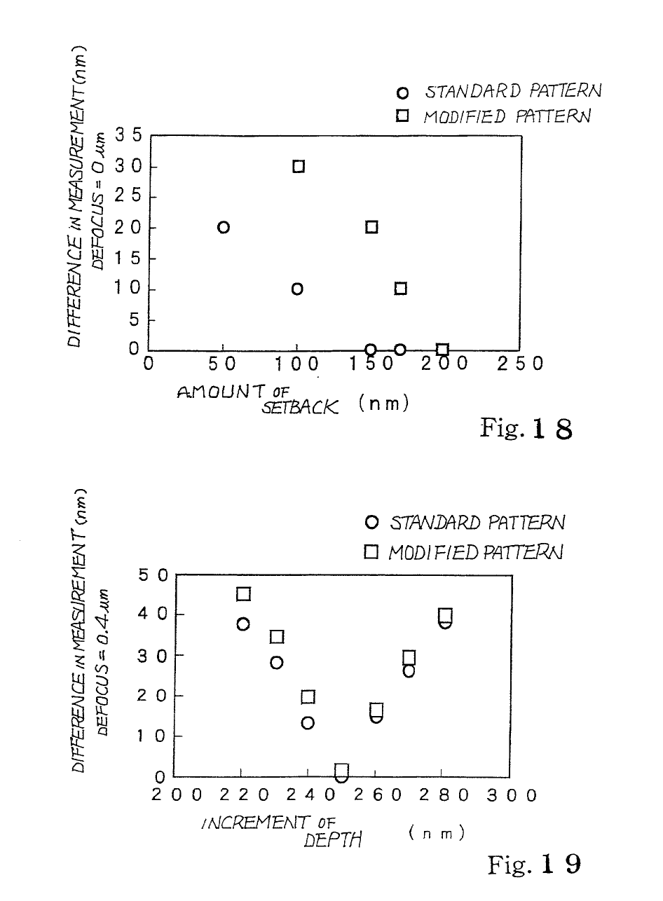

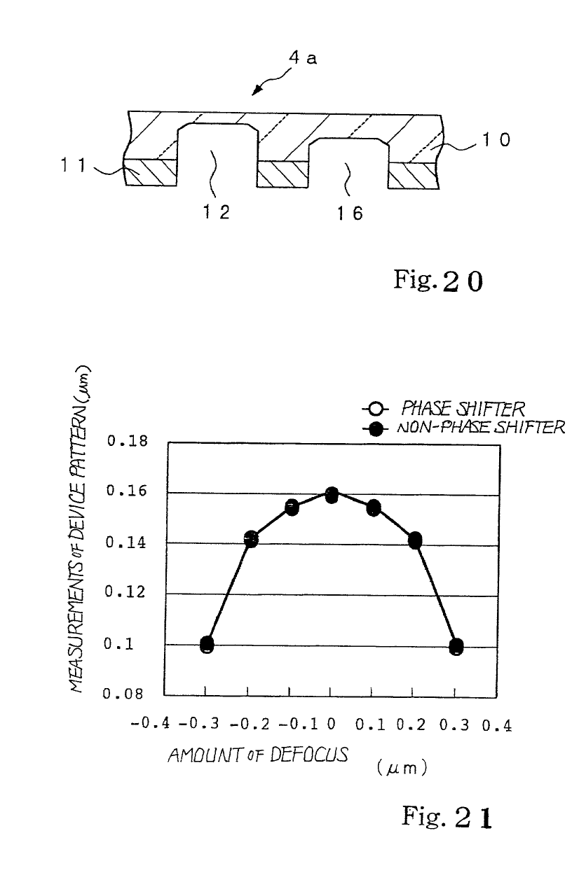

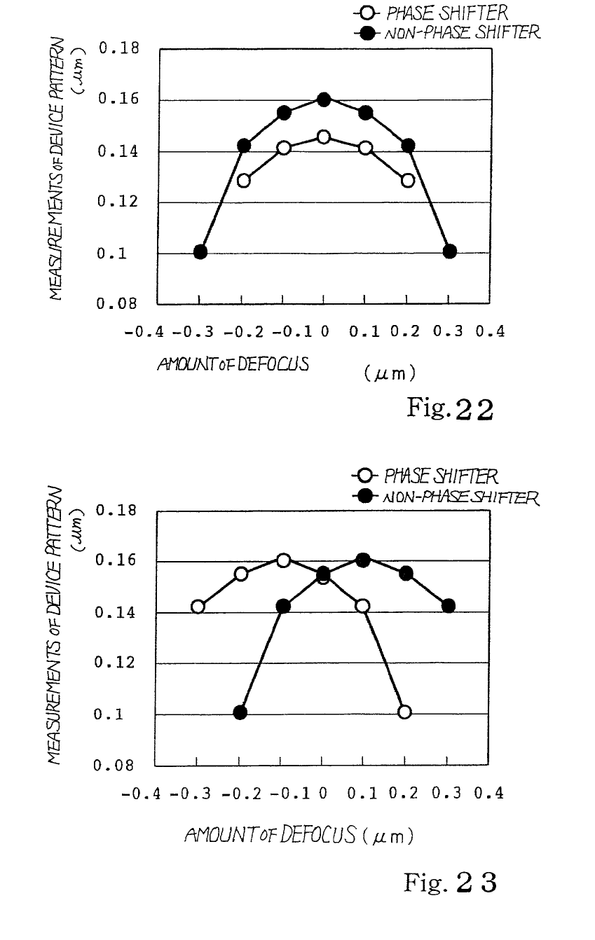

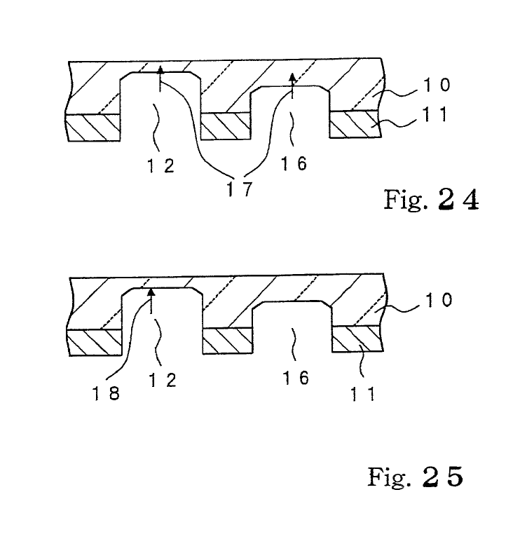

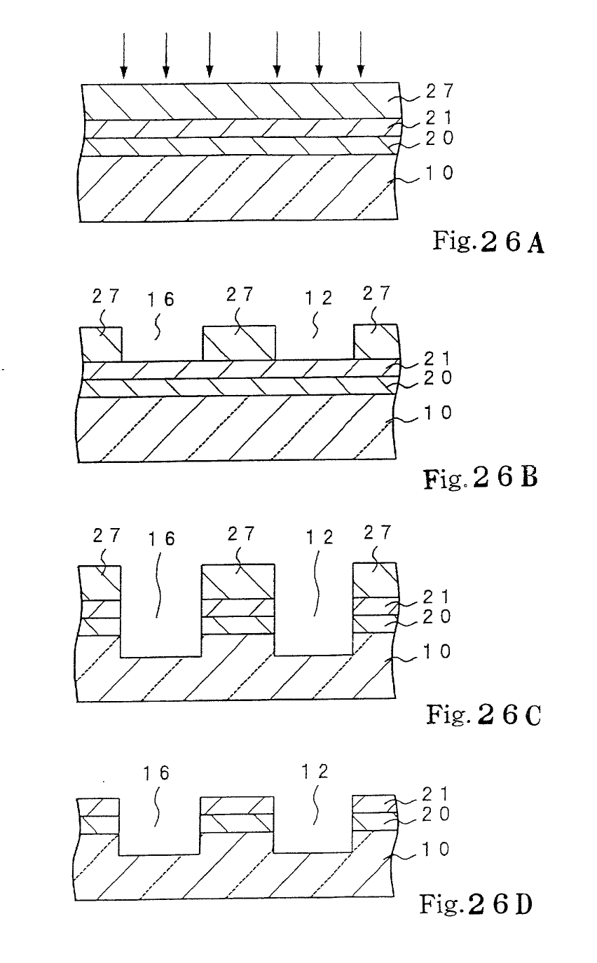

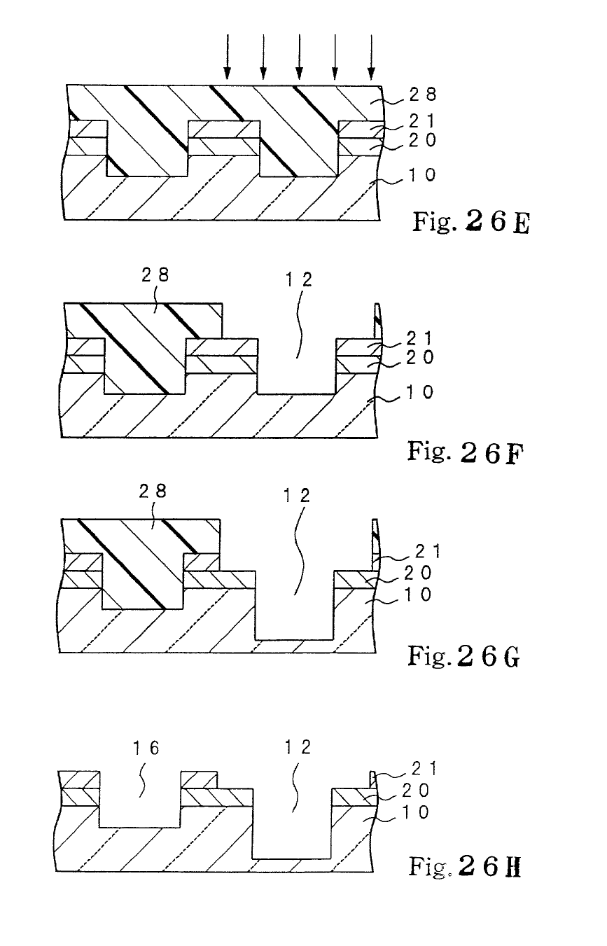

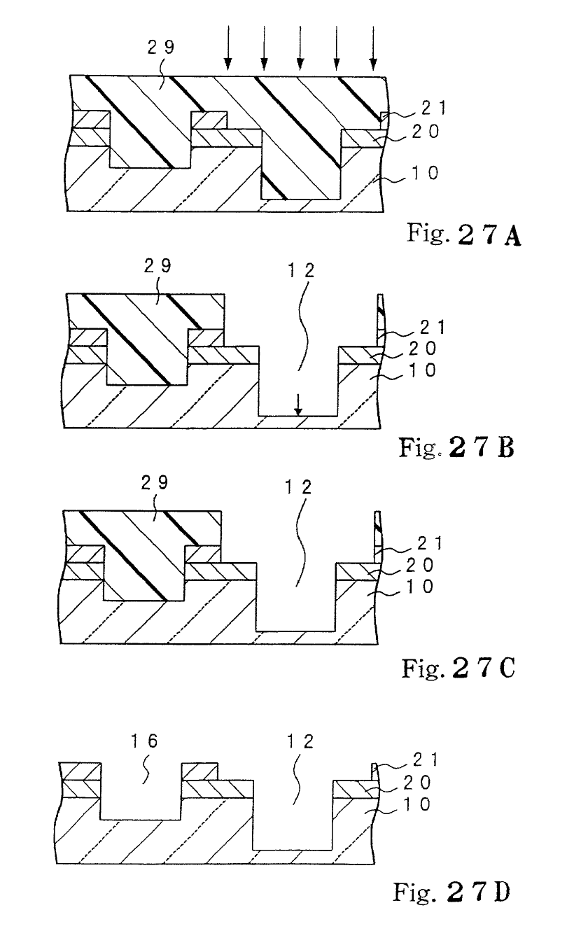

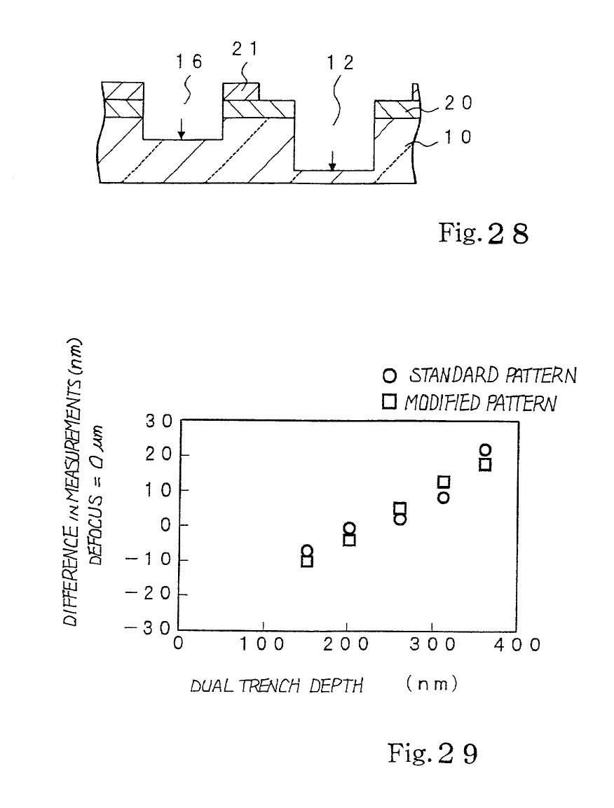

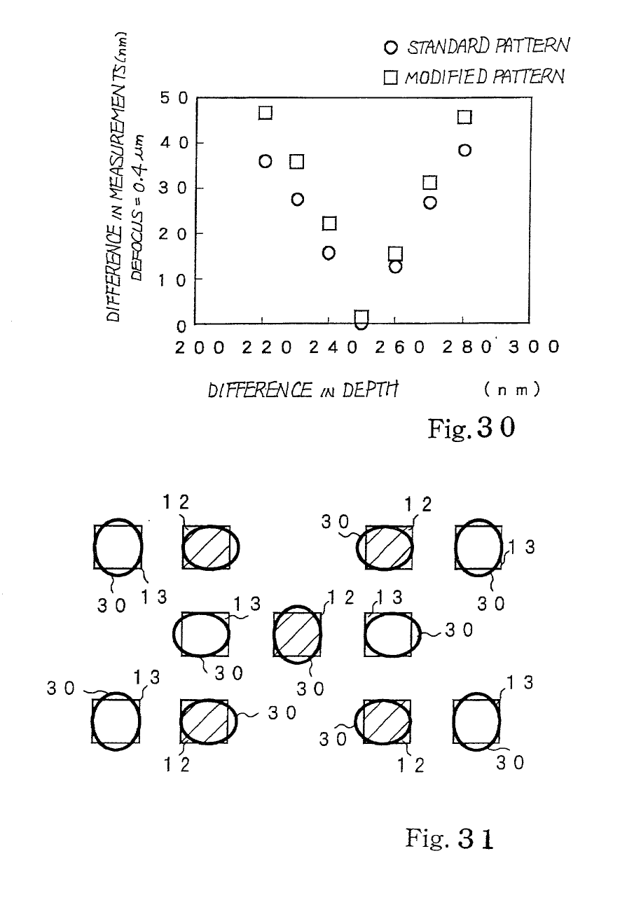

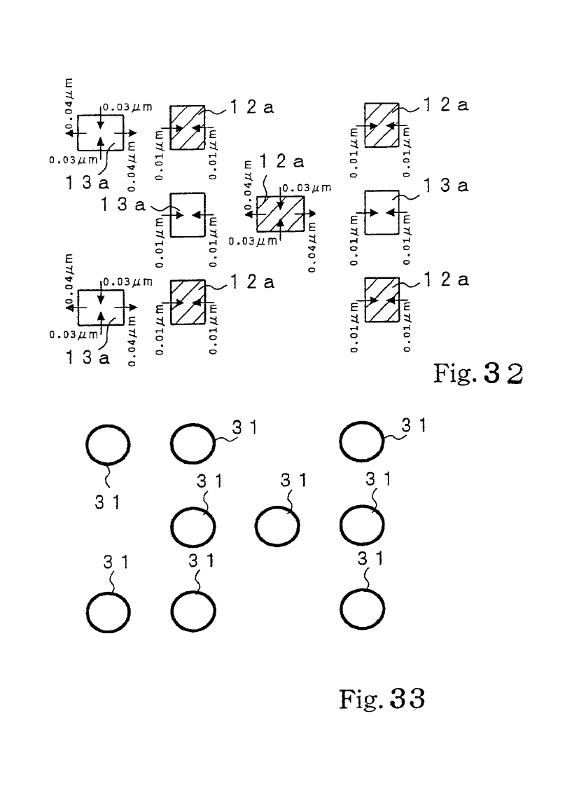

### DESCRIPTION OF THE PREFERRED EMBODIMENTS

First Embodiment

Mask Simulator Used in Repairing Method

Referring to FIG. 5 of the drawings, a mask simulator comprises a light source 1, a bandpass filter 2, a condenser lens 3, an objective lens 5 and a CCD (Charge Coupled Device) camera 6. The light source 1 is implemented by a He lamp or a Xe lamp, and the other component parts 2, 3, 5 and 6 are provided on the optical path of the light radiated from the light source 1. Thus, the component parts of the mask simulator are arranged like those of a projection aligner. The mask simulator is commercially sold. The mask simulator MSM100 is an example of the mask simulator commercially sold in the market, and is manufactured by Carl Zeiβ.

Single Trench Levenson Phase Shift Mask

A single trench Levenson phase shift mask 4 is to be inserted into the gap between the condenser lens 3 and the objective lens 5. The single trench Levenson phase shift mask 4 includes a transparent glass substrate 10, and a photo shied layer 11 is patterned on the lower surface of the transparent glass substrate 10. In this instance, the photo shield layer 11 is formed of chromium. The transparent pattern is hereinbelow referred to as “device pattern”.

As shown in FIG. 6, the transparent glass substrate 10 is partially reduced in thickness, and the thin transparent portions 12 are alternated with thick transparent portions 13. The thin transparent portions 12 serve as a phase shifter, and are designed to shift the rays passing therethrough by 180 degrees with respect to the rays passing through the thick transparent portions 13. The thick transparent portions 13 serve as a non-phase shifter. The thin transparent portions 12 are formed through an etching. The etching proceeds in a direction parallel to the lower surface as well as in the direction normal thereto. For this reason, the trench sidewardly expands, and the side wall defining the trench is retracted from the inner surface of the photo shield pattern as shown.

The light is radiated from the light source 1, and the bandpass filter 2 is transparent to predetermined wavelength rays. The predetermined wavelength rays are incident on the condenser lens 3. The condenser lens 3 shapes the predetermined wavelength light into parallel rays, and supplies the parallel rays to the single trench Levenson phase shift mask 4. The thin transparent portions 12 shift the phase of the parallel rays by 180 degrees, and transmit the phase-shifted rays and non-phase shifted rays to the objective lens 5. The objective lens 5 focuses the phase-shifted/non-phase shifted rays on the CCD camera 6. The CCD camera 6 is movable along the optical path, and measures the light intensity at the position where the device pattern image is defocused. On the CCD camera 6, the device pattern is observed at ten times larger than the device pattern on a photo resist layer formed on a wafer.

Repairing Method for Standard Levenson Phase Shift Mask

Description is hereinbelow made on a method for repairing a single trench Levenson phase shift mask with reference to FIG. 7. First, a reticle or the single trench Levenson phase shift mask 4 is prepared as by step S0. The retide is provided in the mask simulator, and is moved into the gap between the condenser lens 3 and the objective lens 5. The device pattern gets ready to be radiated with the parallel rays.

Subsequently, the light is radiated from the light source 1. The parallel light passes through the device pattern with and without phase shift, and the device pattern is projected onto the CCD camera 6. The light intensity is measured by the CCD camera 6, and a dispersion of light intensity is determined over the device pattern. Thus, the dispersion of light intensity is determined by using the mask simulator as by step S2.

Subsequently, measurements of the device pattern are optically determined on the basis of the dispersion of light intensity. The measurements of the device pattern is determined on the basis of variation of the amount of defocus obtained by moving the CCD camera 6 along the optical path. Otherwise, the dispersion of light intensity is compared with a reference dispersion for the device pattern. The measurements of the device pattern or the comparison result is checked to see whether or not the reticle is to be repaired as by step S3.

If the measurements or the comparison result indicates a defect, the answer is given affirmative NG, and the reticle is repaired through an etching or reproduced as by step S1. The loop consisting of steps S1, S2 and S4 is repeated until the answer at step S3 is given negative.

When the measurements or the comparison result indicates that the reticle is non-defective, the answer is given negative OK, and the repairing work is completed as by step S4.

Step S3 is hereinbelow described in detail with reference to FIGS. 8, 9 and 10. An ideal single trench Levenson phase shift mask is investigated through steps 2 and 3. The measurements of the device pattern are plotted in terms of the amount of defocus in FIG. 8. Dots are indicative of the measurements of the device pattern in the thick transparent portion 13, i.e., the non-phase shifter, and bubbles stand for the measurements of the device pattern in the thin transparent portion 13, i.e., the phase shifter. When the defocus is zero, the device pattern measures 0.16 micron wide in both of the thin transparent portion 12 and the thick transparent portion 13, and the dot is perfectly overlapped with the bubble. Even though the amount of defocus is varied, the dots are still overlapped with the corresponding bubbles.

If the abnormal difference in transmittance takes place in a defective single trench Levenson phase shift mask 4, the measurements of the device pattern in the thin transparent portion 12 are smaller in value than the measurements of the device pattern in the thick transparent portion 13 as shown in FIG. 9. The bubbles are downwardly spaced from the corresponding dots.

On the other hand, when another single trench Levenson phase shift mask 4 contains the abnormal phase difference, the maximum values are equal between the measurements of the device pattern in the thin transparent portion 12 and the measurements of the device pattern in the thick transparent portion 13 as shown in FIG. 10. However, the maximum value of the measurements in the thin transparent portion 12 is at −0.1 micron, and the maximum value of the measurement in the thick transparent portion 13 is at +0.1 micron. Thus, the plots for the phase shifter is laterally deviated from the plots for the non-phase shifter.

The dispersion of light intensity is measured at plural defocusing points by using the mask simulator, and the measurements of the device pattern in the phase shifter and the measurements of the device pattern in the non-phase shifter are determined. The values of the measurements in the phase shifter are compared with the values of the measurements in the non-phase shifter at the different defocusing points to see whether or not the deviation takes place between the corresponding values at each defocusing point. If the values are approximately equal at each defocusing point, the single trench Levenson phase shift mask is decided to be non-defective. However, when a deviation takes place, the single trench Levenson phase shift mask 4 is decided to be defective. The defect mode is depending upon the direction of the deviation.

The repairing work at step S1 is carried out as follows. Assuming now that a single trench Levenson phase shift mask 4 is decided to be defective due to the abnormal difference in transmittance shown in FIG. 9, the transparent glass substrate 10 is sidewardly etched as indicated by arrow 41 in FIG. 11 so that the trenches are widened. The amount of light passing through the thin transparent portions 12 is increased, and the bubbles are upwardly moved. As a result, the dots are overlapped with the corresponding bubbles. On the other hand, if the values at the dots are less than the values of the bubbles, the bubbles indicate that the trenches are too wide. In this situation, the single trench Levenson phase shift mask 4 is redesigned, and reproduced.

When a single trench Levenson phase shift mask is decided to be defective due to the abnormal phase difference, the transparent glass substrate 10 is etched in the direction indicated by arrow 42 (see FIG. 12). The thin transparent portions 12 are reduced in thickness so as to make the dots overlapped with the corresponding bubbles. If the trenches are too deep, the single trench Levenson phase shift mask 4 is reproduced.

A single trench Levenson phase shift mask is produced in step S0 through a process sequence shown in FIGS. 13A to 13L. The single trench Levenson phase shift mask is to be used in a projection aligner equipped with a KrF eximer laser light source. The trenches 12 for the phase shifter 12 are to be of the order of 240 nanometers deep.

First, chromium is deposited over the entire surface of a transparent glass substrate 10, and, thereafter, chromium oxide is deposited over the chromium layer 20. Thus, the chromium layer 20 is laminated on the surface of the transparent glass substrate 10, and is overlaid by the chromium oxide layer 21. Electron beam resist solution is spread over the surface of the chromium oxide layer 21 so that an electron beam resist layer 22 is formed on the chromium oxide layer 21. Areas assigned to the phase shifter 12 and the non-phase shifter 13 are exposed to an electron beam as shown in FIG. 13A.

A latent image for the phase shifter 12 and the non-phase shifter 13 is produced in the electron beam resist layer 22. The latent image is developed. Thus, the electron beam resist layer 22 is patterned into an etching mask, which is also labeled with reference numeral 22 in FIG. 13B. The areas assigned to the phase shifter 12 and the non-phase shifter 13 are exposed to hollow spaces of the etching mask 22.

Using the etching mask, the chromium oxide layer 21 and the chromium layer 20 are selectively removed from the surface of the transparent glass substrate 10 by using a dry anisotropic etching technique as shown in FIG. 13C. The etching mask 22 is stripped off, and the patterned chromium oxide layer 21 is exposed as shown in FIG. 13D.

Subsequently, a resist layer 23 is formed on the entire surface of the resultant structure, and an area assigned to the phase shifter 12 is exposed for producing a latent image in the resist layer 23 as shown in FIG. 13E. The latent image is developed so that a part of the chromium oxide layer 21 and a part 12 of the transparent glass substrate 10 to be reduced in thickness are exposed to the hollow space formed in the patterned resist layer 23 as shown in FIG. 13F.

Using the patterned resist layer 23 as an etching mask, the chromium oxide layer 21 is selectively etched so that a part of the chromium layer 20 is exposed to the hollow space. Using the chromium layer 20 as an etching mask, the transparent glass substrate 10 is anisotropically etched by a predetermined depth d as shown in FIG. 13G. Thus, the thin transparent portion 12 is formed in the transparent glass substrate 10. The depth d ranges from 70 nanometers to 140 nanometers.

The patterned resist layer 23 is stripped off. Then, the thick transparent portion 13 is exposed to the hollow space formed in the lamination of the chromium layer 20 and the chromium oxide layer 21 as shown in FIG. 13H. However, the thin transparent portion 12 is not completed.

The resultant structure shown in FIG. 13H is checked to see how much the difference in transmittance and the phase difference are as similar to steps S2 and S3. When the difference in transmittance and the phase difference are determined, the target profile of the phase shifter 12 is designed, and the phase shifter 12 is shaped as follows.

The resultant structure is covered with a resist layer 24, and the area assigned to the phase shifter 12 is exposed so that the latent image is produced in the resist layer 24, again, as shown in FIG. 13I. The latent image is developed so that the part of the chromium layer 20 and the thin transparent portion 12 are exposed to the hollow space formed in the resist layer 24 as shown in FIG. 13J.

Using the chromium layer 20 as an etching mask, the thin transparent portion 12 is isotropically etched. The trenches are not only deepened but also widened. In this instance, the isotropic etching is controlled in such a manner that the side wall defining each trench is set back by 100 nanometers to 170 nanometers. The amount of set-back is labeled with “W” in FIG. 13K. When the isotropic etching is terminated, the trench is deepened also by 100 nanometers to 170 nanometers. If the set-back measures 150 nanometers wide, the trenches are deepened also by 150 nanometers, and the trenches were to be anisotropically etched by 90 nanometers deep in step 13G.

Finally, the patterned resist layer 24 is stripped off, and the single trench Levenson phase shift mask 4 is produced as shown in FIG. 13L.

The single trench Levenson phase shift mask thus produced is checked to see whether the difference in transmittance and the phase difference are normal or abnormal in steps S2 and S3.

The abnormal phase difference due to the shallow trenches is found in the single trench Levenson phase shift mask through steps S2 and S3. Then, the single trench Levenson phase shift mask is taken out from the mask simulator, and is repaired in step S1. FIGS. 14A to 14D show the repairing work in step S1.

First, the single trench Levenson phase shift mask is covered with a resist layer 25, and the area assigned to the phase shifter 12 is exposed to produce the latent image as shown in FIG. 14A. The latent image is developed so that a hollow space is formed in the resist layer 25. The trenches or the phase shifter 12 is exposed to the hollow space as shown in FIG. 14B.

The trenches are reshaped through a wet etching as shown in FIG. 14C. The trenches are deepened in the wet etchant, and the bottom surfaces 44 are further depressed. Although the side walls 43 are further retracted in the wet etching, the increment of the difference in transmittance is ignoreable. In other words, the wet etchant is regulated in such a manner that the wet etching strongly proceeds in the vertical direction. The patterned resist layer 25 is stripped off, and the single trench Levenson phase shift mask is repaired as shown in FIG. 14D.

If the increment is serious, the single trench Levenson phase shift mask is to be reproduced. In case, where the phase shifter 12 is too thin, the single trench Levenson phase shift mask is redesigned, and is produced in step S1. Although the amount of set-back is too large, the single trench Levenson phase shift mask is redesigned, and is reproduced. However, if the abnormal difference in transmittance is due to a small amount of light transmitted through the phase shifter 12, the trenches are reshaped through the process shown in FIGS. 14A to 14D. However, the wet etchant is selected in such a manner that the etching proceeds in the lateral direction. The reduction in thickness may be not ignoreable. If so, the single trench Levenson phase shift mask is redesigned, and reproduced.

The abnormal difference in transmittance may be due to the large amount of set-back. The single trench Levenson phase shift mask is to be redesigned and reproduced. Especially, the amount of the isotropic etching is to be reduced, and the decrement of the depth is to be compensated by using the anisotropic etching as follows.

FIGS. 15A to 15F shows a process for reproducing the single trench Levenson phase shift mask. The process is similar to the process for producing a single trench Levenson phase shift mask (see FIGS. 13A to 13L) until the step shown in FIG. 13F. The portion of the transparent glass substrate 10 assigned to the phase shifter 12 is anisotropically etched so as to form the trenches. The time over which the anisotropic etching is continued is, by way of example, prolonged so as to make the trenches deeper than the trench of the previously produced single trench Levenson phase shift mask as shown in FIG. 15A. The patterned resist layer 23 is stripped off, and the non-phase shifter 13 is exposed as shown in FIG. 15B. The difference in transmittance and the phase difference are determined as similar to steps S2 and S3. The amount of set-back is smaller than that in the previously produced single trench Levenson phase shift mask.

The resultant structure is covered with a resist layer 26, and the areas assigned to the phase shifter 12 are exposed so as to form the latent image as shown in FIG. 15C. The latent image is developed, and the patterned resist layer 26 is formed with the hollow space to which the phase shifter is exposed as shown in FIG. 15D.

The trenches are reshaped through an isotropic etching as shown in FIG. 15E. The time period for the isotropic etching is shorter than that for the previously produced single trench Levenson phase shift mask, because the trenches have been deepened through the anisotropic etching. The shorter the isotropic etching, the smaller the amount of set-back. For this reason, when the isotropic etching is ended, the trenches are as deep as those in the previously produced single trench Levenson phase shift mask, and the side walls are less retracted from the inner edges of the chromium layer 20. The patterned resist layer 26 is stripped off, and the single trench Levenson phase shift mask is completed as shown in FIG. 15F. Thus, the difference in transmittance is corrected.

As will be understood from the foregoing description, the single trench Levenson phase shift mask is investigated by analyzing the device pattern on the CCD camera 6 obtained at different defocusing points, and the trenches of the phase shifter are reshaped when the difference in transmittance or the phase difference are decided to be abnormal. Although the single trench Levenson phase shift mask has the three-dimensional contour, both of the difference in transmittance and the phase difference are influential in the measurements of the device pattern, and whether the difference in transmittance and the phase difference are normal or abnormal is determinable through comparison of the device pattern between the portion assigned to the phase shifter and the portion assigned to the non-phase shifter. When the single trench Levenson phase shift mask is decided to be defective, the trenches of the phase shifter are reshaped so as to rescue the single trench Levenson phase shift mask from disposal.

Repairing Method for Modified Levenson Phase Shift Mask

FIG. 16A shows the thin transparent portions 12 and the thick transparent portions 13 laid on the standard pattern. Hatching lines are given to the thin transparent portions 12 so as to be easily discriminated from the thick transparent portions 13. As will be understood, the thin transparent portions 12 are alternated with the thick transparent portions 13 not only in each row but also in each column. The thin transparent portions 12 are equal in size to the thick transparent portions 13. In this instance, both thin and thick transparent portions respectively occupy square areas of 0.15 micron by 0.15 micron. The thin transparent portions 12 and the thick transparent portions 13 are alternated with one another at pitches of 0.3 micron.

FIG. 16B shows a modified single trench Levenson phase shift mask. The modified single trench Levenson phase shift mask has a supplementary phase shifter 12b and a supplementary non-phase shifter 13b as well as the phase shifter 12 and the non-phase shifter 13. The phase shifter 12 and the supplementary phase shifter 12b are indicated by using the hatching lines in the figure. The phase shifter 12 and the non-phase shifter 13 occupy relatively wide square areas of 0.15 micron by 0.15 micron, respectively, and the supplementary phase shifter 12b and the supplementary non-phase shifter 13b occupy relatively narrow square areas of 0.12 micron by 0.12 micron. The relatively wide square areas and the relatively narrow square areas are arranged at center-to-center pitches of 0.3 micron. The relatively wide square areas for the phase shifter 12 are arranged in such a manner that the adjacent square areas in the same row and in the same column are never assigned to the phase shifter 12 and the supplementary phase shifter 12b. Similarly, the relatively narrow square areas for the supplementary phase shifter 12b are arranged in such a manner that the adjacent square areas in the same row and in the same column are never assigned to the supplementary phase shifter 12b and the phase shifter 12. The relatively wide square areas for the non-phase shifter 13 are also arranged in such a manner that the adjacent square areas in the same row and in the same column are never assigned to the non-phase shifter 13 and the supplementary non-phase shifter 13b. Furthermore, the relatively narrow square areas for the supplementary non-phase shifter 13b are arranged in such a manner that the adjacent square areas in the same row and in the same column are never assigned to the supplementary non-phase shifter 13b and the non-phase shifter 13. The pattern shown in FIG. 16A and the pattern shown in FIG. 16B are hereinbelow referred to as “standard pattern” and “modified pattern”, respectively.

The modified single trench Levenson phase shifter is preferable to transfer a pattern image shown in FIG. 17A. In FIG. 17A, reference numeral 15 designates square areas to be exposed to light. In order to transfer the pattern image to a photo resist layer, the standard single trench Levenson phase shift mask have a standard pattern shown in FIG. 17B.

Focusing attention on the thick transparent portion labeled with reference numeral 13 in FIG. 17B, the thick transparent portion 13 is widely spaced from the thin transparent portion 12 in the same row. However, the distance between the thick transparent portion 13 and the thin transparent portion in the same column is relatively narrow. A manufacturer is assumed to transfer the pattern shown in FIG. 15 to a photo resist layer. The measurements of the latent image of the phase shifter 12 become different from the measurements of the latent image of the non-phase shifter 13. This means that the difference in transmittance is not zero. Even if the manufacturer tries to decrease the difference in transmittance to zero through the regulation of the amount of set-back, the initial difference is maintained. Although the reason for the initial difference is not clear, the initial difference may be due to the asymmetry in the pattern. Thus, the standard single trench Levenson phase shift mask for the pattern image shown in FIG. 17A is hardly rescued from the abnormal difference in transmittance. In other words, the abnormal difference in the transmittance is seriously influenced on the standard three-dimensional Levenson phase shift mask.

On the other hand, the modified single trench Levenson phase shift mask shown in FIG. 16B has the relatively narrow square areas for the supplementary phase shifter 12b and the supplementary non-phase shifter 13b between the thin transparent portion 12 and the thick transparent portions 13 widely spaced therefrom. The relatively wide squares and the relatively narrow squares are arranged at constant pitches so that the regulation of the setback is uniformly influenced. The rays passing through the supplementary phase shifter 12b and the supplementary non-phase shifter 13b do not produce a latent image as deep as the latent image produced by the rays passing through the phase shifter 12 and the non-phase shifter 13. For this reason, the latent image shown in FIG. 17A is produced in the photo resist layer.

The difference in measurement is assumed to take place between the phase shifter and the non-phase shifter in the optical image of the standard pattern shown in FIG. 16A and between the phase shifter and the non-phase shifter in the optical image of the modified pattern shown in FIG. 16B. If the abnormal difference in measurement is due to the difference in transmittance, the side walls defining the trenches are to be set back. When the amount of setback is increased, the difference in measurement is decreased. FIG. 18 shows a relation between the amount of setback and the value of the difference in measurement at the defocusing point of zero for the standard pattern and the modified pattern. In this instance, when the side walls in the standard single trench Levenson phase shift mask are set back by 150 nanometers, the difference in measurement on the optical image of the standard pattern is decreased to zero. In other words, the difference in transmittance is decreased to zero at 150 nanometers. Similarly, when the side walls in the modified single trench Levenson phase shift mask are set back by 200 nanometers, the difference in measurement is decreased to zero. In other words, the difference in transmittance is decreased to zero at 200 nanometers. Thus, the difference in transmittance in the modified single trench Levenson phase shift mask is measurable by using the mask simulator, and is correctable by varying the amount of setback.

The standard pattern shown in FIG. 16A has the thin transparent portions 12 and the thick transparent portions 13 which respectively occupy the square areas each measuring 0.15 micron by 0.15 micron. The square areas are arranged at pitches of 0.3 micron. On the other hand, the modified pattern shown in FIG. 16B has the wide thin transparent portions 12, the narrow thin transparent portions 12b, the wide thick transparent portions 13 and the narrow thick transparent portions 13b. The wide thin transparent portions 12 and the wide thick transparent portions 13 respectively occupy the wide square areas each measuring 0.15 micron by 0.15 micron, and the narrow thin transparent portions 12b and the narrow thick transparent portions 13b respectively occupy the narrow square areas each measuring 0.12 micron by 0.12 micron. The wide thin transparent portions 12, the narrow thin transparent portions 12b, the wide thick transparent portions 13 and the narrow thick transparent portions 13b are arranged at center-to-center pitches of 0.3 micron. However, when the standard/modified single trench Levenson phase shift masks are produced, an error unavoidably takes place at ±5 percent. For this reason, each actual product of the standard single trench Levenson phase shift mask has the thin transparent portions 12 and the thick transparent portions 13 which respectively occupy the square areas each measuring 0.15 micron ±7.5 nanometers by 0.15 micron ±7.5 nanometers at pitches of 0.3 microns ±15 nanometers. If the difference in measurement is decreased as shown in FIG. 18, the abnormal difference in transmittance is eliminated from the actual product at the setback of 150 nanometers ±7.5 nanometers. On the other hand, in each actual product of the modified single trench Levenson phase shift mask, the wide thin transparent portions 12 and the wide thick transparent portions 13 respectively occupy the wide square areas each measuring 0.15 micron ±7.5 nanometers by 0.15 micron ±7.5 nanometers, and the narrow thin transparent portions 12b and the narrow thick transparent portions 13b respectively occupy the narrow square areas each measuring 0.12 micron ±6.0 nanometers by 0.12 micron ±6.0 nanometers. The wide thin transparent portions 12, the narrow thin transparent portions 12b, the wide thick transparent portions 13 and the narrow thick transparent portions 13b are arranged at center-to-center pitches of 0.3 micron ±15 nanometers. The expression “A±B” means the range from “A+B” to “A−B”.

On the other hand, if the difference in measurement is due to the abnormal phase difference, the depth of the trenches is to be increased. When the depth is increased, the difference in measurement is decreased. FIG. 19 shows a relation between the depth and the value of the difference in measurement at the defocusing point of 0.4 micron for the standard pattern and the modified pattern. In this instance, when the trenches in the standard single trench Levenson phase shift mask are deepened to 250 nanometers, the difference in measurement on the optical image of the standard pattern is decreased to zero. In other words, the phase difference is adjusted to 180 degrees at 250 nanometers deep. Similarly, when the trenches in the modified single trench Levenson phase shift mask are deepened to 250 nanometers, the difference in measurement is decreased to zero. In other words, the phase difference is adjusted to 180 degrees at 250 nanometers deep. Thus, the phase difference in the modified single trench Levenson phase shift mask is measurable by using the mask simulator, and is correctable by varying the depth of the trenches. When the modified single trench Levenson phase shift mask is produced, the error unavoidably takes place. Each actual product of the modified single trench Levenson phase shift mask has the depth of 250 nanometers±12.5 nanometers.

As will be understood, the repairing method for the standard single trench Levenson phase shift mask is applicable to the modified single trench Levenson phase shift mask. The device pattern of the standard single trench Levenson phase shift mask and the device pattern of the modified single trench Levenson phase shift mask may have the measurements, i.e., the length, width and depth different from those shown in FIGS. 16A and 16B. Even so, the difference in transmittance and the deviation from 180 degrees are also determined on the basis of the difference in measurement on the optical image between the phase shifter and the non-phase shifter in the optical image of the device pattern.

The single trench Levenson phase shift mask has the three dimensional transparent portions. The optical simulation of the prior art repairing method is applicable to the two dimensional device pattern. However, the application of the prior art optical simulation to the three dimensional pattern is not successful. The optical simulation in the repairing method according to the present invention is carried out by using the mask simulator like the projection aligner, and the single trench Levenson phase shift mask is exposed to the light. The dispersion of light intensity of the transmitted light is directly measured by means of an image pick-up device such as, for example, the CCD camera 6, and the dispersion of light intensity is analyzed in such a manner as to determine the difference in measurement on the optical image between the phase shifter and the non-phase shifter in the optical image. The difference in transmittance between the phase shifter and the non-phase shifter and the phase difference of transmitted rays between the phase shifter and the non-phase shifter are measurable as the difference in measurement on the optical image between the phase shifter and the non-phase shifter in the optical image. For this reason, the single trench Levenson phase shift mask is successfully analyzed through the optical simulation, and the abnormal difference in transmittance and the abnormal phase difference is eliminated from the single trench Levenson phase shift mask by changing the surface profile.

Second Embodiment

Dual Trench Levenson Phase Shift Mask

FIG. 20 shows the structure of a dual trench Levenson phase shift mask. The dual trench Levenson phase shift mask 4a includes a transparent glass substrate 10 and a photo shield layer 11. Although only one deep trench and only one shallow trench are shown in FIG. 20, plural deep trenches and plural shallow trenches are formed in the transparent glass substrate 10. The deep trenches define thin transparent portions, which serve as a phase shifter 12. The shallow trenches define thick transparent portions, which serve as a non-phase shifter 16. The difference in depth makes the rays passing through the thin transparent portions different in phase from the rays passing through the thick transparent portions. In this instance, the deep trenches are as deep as 500 nanometers, and the shallow trenches are adjusted to 240 nanometers in depth. The photo shield layer 11 is formed of chromium, and does not penetrate into the deep/shallow trenches.

The mask simulator shown in FIG. 5 is available for the optical simulation on the dual trench Levenson phase shift mask. If the abnormal difference in transmittance and the abnormal phase difference do not take place in the dual trench Levenson phase shift mask, the measurements of the phase shifter 12 in the optical image are coincident with the measurements of the non-phase shifter 16 in the optical image at all defocusing points as shown in FIG. 21.

However, when the optical simulation is carried out for a defective dual trench Levenson phase shift mask due to the abnormal difference in transmittance, the measurements of the device pattern in the optical image of the phase shifter 12 are smaller in value than the measurements of the device pattern in the optical image of the non-phase shifter 16, and the plots for the phase shifter 12 are spaced from the plots for the non-phase shifter 16 as shown in FIG. 22 in the direction of the axis of coordinates. On the other hand, the abnormal phase difference makes the plots for the phase shifter 12 and the plots for the non-phase shifter 16 spaced from one another in the direction of the abscissa as shown in FIG. 23. Thus, the plots exhibit the tendency similar to the plots for the phase shifter 12 and the non-phase shifter 13 in the single trench Levenson phase shift mask.

The defective dual trench Levenson phase shift mask is rescued from the abnormal difference in transmittance as shown in FIG. 24. The depth of the deep trenches and the depth of the shallow trenches are varied until the difference in transmittance between the phase shifter 12 and the non-phase shifter is decreased to zero. On the other hand, when the abnormal phase difference takes place between the rays passing through the phase shifter 12 and the rays passing through the non-phase shifter 16, only the depth of the deep trench is increased as shown in FIG. 25.

Repairing Method for Dual Trench Levenson Phase Shift Mask

The repairing method for the dual trench Levenson phase shift mask 4a is similar to the repairing method shown in FIG. 7. However, the steps of the repairing method shown in FIG. 7 are slightly modified as follows.

In step S0, the dual trench Levenson phase shift mask is produced through the process shown in FIGS. 26A to 26H. The process starts with preparation of the transparent glass substrate 10. Chromium and chromium oxide are successively deposited over the surface of the transparent glass substrate 10, and form a chromium layer 20 and a chromium oxide layer 21, respectively. Electron beam resist is spread over the entire surface of the chromium oxide layer 21, and forms an electron beam resist layer 27 on the chromium oxide layer 21. A latent image for the phase shifter 12 and the non-phase shifter 16 are drawn in the electron beam resist layer 27 with an electron beam as shown in FIG. 26A

The latent image is developed. Then, the electron beam resist layer 27 is patterned, and areas assigned to the phase shifter 12 and the non-phase shifter 16 are exposed to the hollow space formed in the patterned electron beam resist layer 27 as shown in FIG. 26B.

Using the patterned electron beam resist, the chromium oxide layer 21, the chromium layer 20 and the transparent glass substrate 10 are selectively etched by using an anisotropic dry etching technique so that shallow trenches are formed in the surface portions of the transparent glass substrate 10 assigned to the phase shifter 12 and the non-phase shifter 16. The shallow trenches for the phase shifter 12 are equal in depth to the shallow trenches for the non-phase shifter 16 as shown in FIG. 26C. The patterned resist layer 27 is stripped off. The resultant structure is formed with the shallow trenches as shown in FIG. 26D.

The resultant structure is covered with a resist layer 28, and a latent image for the deep trenches is produced in the resist layer 28 as shown in FIG. 26E. The latent image is developed so that the resist layer is removed from the area assigned to the phase shifter 12 as shown in FIG. 26F.

Using the patterned resist layer 28 as an etching mask, the trenches are deepened through an anisotropic dry etching, and the deep trenches are formed in the portions assigned to the phase shifter 12 as shown in FIG. 26G.

The patterned resist layer 28 is stripped off, and the dual trench Levenson phase shift mask is obtained as shown in FIG. 26H. The dual trench Levenson phase shift mask may be used in a projection aligner with a KrF excimer laser light source. In this instance, the deep trenches and the shallow trenches are designed to be 470 nanometers deep and 220 nanometers deep, respectively, and the deep trenches are twice deeper than the shallow trenches.

The dual trench Levenson phase shift mask thus produced is investigated by using the mask simulator shown in FIG. 5. The dispersion of light intensity is measured at plural defocusing points (see step S2 in FIG. 7), and the optical images at the plural defocusing points are analyzed to see whether or not the abnormal difference in transmittance and the abnormal phase difference take place in the dual trench Levenson phase shift mask (see step S3 in FIG. 7).

If the dual trench Levenson phase shift mask is decided to be defective due to the abnormal phase difference, the manufacturer checks the analysis to see whether or not the dual trench Levenson phase shift mask is to be rescued. When the abnormal difference in transmittance is due to the shortage of light passing through the phase shifter, the manufacturer determines the appropriate thickness of the thin transparent portions, and the dual trench Levenson phase shift mask is repaired as shown in FIGS. 27A to 27D.

First the dual trench Levenson phase shift mask is covered with a resist layer 29, and a latent image for the phase shifter 12 is produced in the resist layer 29 as shown in FIG. 27A.

The latent image is developed so that the deep trenches are exposed to the hollow space formed in the patterned resist layer 29. Using the patterned resist layer 29, the transparent glass substrate 10 is selectively etched by using the anisotropic dry etching technique as shown in FIG. 27B so that the thin transparent portions for the phase shifter 12 are adjusted to the appropriate thickness as shown in FIG. 27C. The patterned resist layer 29 is stripped off, and the dual trench Levenson phase shift mask shown in FIG. 27D is subjected to the investigation, again.

If the abnormal phase difference is due to the over-etching in step 26G, the manufacturer decides that a new dual trench Levenson phase shift mask is to be reproduced.

On the other hand, if the abnormal difference in transmittance is observed in the optical analysis, the manufacturer checks the result of the optical analysis to see whether or not the abnormal difference in transmittance is correctable. The dual trench Levenson phase shift mask is subjected to the anisotropic etching so as to deepen both deep and shallow trenches as shown in FIG. 28. While rays are passing through a dual trench Levenson phase shift mask, the diffracted rays are partially eclipsed by the side surfaces defining the deep/shallow trenches, and standing waves take place. The amount of light eclipsed is increased together with the depth of the trenches. The intensity of the standing waves is controllable by changing the depth of the trenches formed in the dual trench Levenson phase shift mask. When the abnormal difference in transmittance takes place in the dual trench Levenson phase shift mask, the difference in transmittance is decreased to zero by controlling the intensity of the standing waves. The above-described controlling technique is described by S. Ishida et al., Proc. SPIE, vol. 3096, page 333, 1997. H. Kanai et al. also reported the controlling technology (see Proc. SPIE, vol. 2793, 165 page, 1996).

If the abnormal difference in transmittance is resulted from the thin phase shifter 12 and the thin non-phase shifter 16, a new dual trench Levenson phase shift mask is to be reproduced.

As described hereinbefore, both of the phase shifter 12 and the non-phase shifter 16 are formed through an anisotropic etching, and any wet etching technique is not used. However, a wet etching is effective against rough surfaces. For this reason, the dual trench Levenson phase shift mask may be finished through the wet etching. Namely, both thin and thick transparent portions 12/16 may be slightly etched so as to make the bottom surfaces of the deep/shallow trenches smooth.

As described hereinbefore, when the abnormal difference in transmittance takes place, both of the deep trenches and the shallow trenches are concurrently etched so that the difference in transmittance is decreased to zero. Assuming now that the abnormal difference in transmittance is observed in dual trench Levenson phase shift masks which have the standard pattern (see FIG. 16A) and the modified pattern (see FIG. 16B), respectively, the dual trench Levenson phase shift masks are subjected to the regulation of the depth so as to be decreased in depth. The increment in depth of the shallow trenches is referred to as “dual trench depth”. The difference in measurement at the defocusing point of zero is varied together with the dual trench depth as shown in FIG. 29. Since the deep trenches and the shallow trenches are subjected to the anisotropic etching on the same conditions, the difference in depth between the deep trenches and the shallow trenches are theoretically not changed. In this instance, the difference in depth between the deep trenches and the shallow trenches are constant around 250 nanometers. The difference in transmittance is decreased to zero at the dual trench depth of the order of 220 nanometers in both of the dual trench Levenson phase shift mask formed with the standard pattern and the dual trench Levenson phase shift mask formed with the modified pattern as shown in FIG. 29. As described hereinbefore, the error of the order of 5% is unavoidable. When the error is taken into account of, the difference in measurement is decreased to zero at the dual trench depth of (220 nm±11 nm).

On the other hand, when the deep trenches are deepened against the abnormal phase difference, the phase difference is varied together with the difference in depth between the deep trenches and the shallow trenches a shown in FIG. 30. The axis of coordinates is indicative of the differences in measurements in the optical images of the standard/modified patterns between the phase shifter and the non-phase shifter at the defocusing point of 0.4 micron, and the abscissa indicates the difference in depth between the deep trenches and the shallow trenches. In this instance, the dual trench depth, i.e., the depth of the shallow trenches is constant at 250 nanometers. Even if the dual trench depth is varied, the variation of the plots in FIG. 30 is negligible. From FIG. 30, when the difference in depth between the deep trenches and the shallow trenches is regulated to 250 nanometers, both of the dual trench Levenson phase shift mask formed with the standard pattern and the dual trench Levenson phase shift mask formed with the modified pattern are adjusted to 180 degrees. The difference in depth is fallen within the range of 250 nm±12.5 nm when the unavoidable error is taken into account.

As will be understood, the defective dual trench Levenson phase shift masks are repaired by regulating both deep and shallow trenches or the deep trenches to appropriate depth. Although the plots shown in FIGS. 29 and 30 are available for the repairing work on the dual trench Levenson phase shift masks formed with the standard/modified patterns of the predetermined dimensions and pitches, the relation between the difference in measurement and the dual trench depth and the relation between the difference in measurement and the difference in depth are determinable for the standard/modified patterns different in measurements of square areas and the pitches from those shown in FIGS. 16A and 16B. Using the plots, the manufacturer can adjust the difference in transmittance and the phase difference to zero and 180 degrees.

The optical analysis is also accurately carried out on the basis of the optical images of the device patterns such as the standard/modified pattern, and the increment of depth is determined in such a manner that the difference in measurement on the optical image of the device pattern between the phase shifter and the non-phase shifter. Although the dual trench Levenson phase shift mask is also three dimensional, the defective dual trench Levenson phase shift masks are repaired through the method according to the present invention. The optical images are taken by using the CCD camera. For this reason, the optical analysis is completed within a short time. Thus, the Levenson phase shift masks are repaired through the method according to the present invention.

Third Embodiment

FIG. 31 shows a device pattern formed in yet another Levenson phase shift mask. A method for repairing the Levenson phase shift mask implementing the third embodiment includes additional steps for a preliminary pattern correcting work between the step S0 and step S2. The other steps, i.e., steps S0, S2, S3, S1 and S4 are similar to those of the method implementing the first embodiment (see FIG. 7), and, for this reason, description is focused on the additional steps.

The device pattern shown in FIG. 31 has a phase shifter 12 and a non-phase shifter 13. The phase shifter 12 and the non-phase shifter 13 are similar to those of the Levenson phase shift mask 4 shown in FIG. 6. Namely, the phase shifter 12 and the non-phase shifter 13 are implemented by thin transparent portions and thick transparent portions, respectively. The thin transparent portions occupy square areas with hatching lines, and the thick transparent portions of the non-phase shifter 13 occupy square areas without hatching lines. The square areas are arranged selected lattice points, but the other lattice points are vacant or covered with the photo-shield layer. Each of the square areas for the phase shifter 12 is adjacent to the square areas for the non-phase shifter 13 or the vacant areas. As a result, the square areas are arranged at irregular pitches.

The first additional step is to obtain an optical image of the device pattern shown in FIG. 31 by using the mask simulator. When the Levenson phase shift mask is exposed to the laser light beam, the laser light is transmitted through the thin/thick transparent portions, and a dispersion of light intensity is determined on the CCD camera 6. The dispersion of light intensity is analyzed. Then, the thin/ thick transparent portions are observed as elliptical images 30 on the CCD camera 6. The major axes of the elliptical images are selectively directed to a perpendicular direction of the lattice and a lateral direction of the lattice. The square areas are adjacent to the wide space and the narrow space, and the major axis of the elliptical image is directed to the wide space. This phenomenon is due to different influence of the adjacent square transparent portions. As a result, the major axes are selectively directed to the perpendicular and lateral directions of the lattice.

The second additional step is to correct the device pattern. The thin transparent portions and the thick transparent portions are corrected in such a manner as to be shortened in the directions of the major axes elongated in the directions of minor axes. FIG. 32 shows the preliminary correcting work. In this instance, the thin transparent portions 12a in the uppermost row are, by way of example, narrowed in the lateral direction. The thick transparent portion 13a in the upper most row is laterally elongated and perpendicularly narrowed. Thus, the square areas are reshaped into rectangular areas as shown.

The first additional step and the second additional step are repeated until circular optical images are observed on the CCD camera 6 as shown in FIG. 33.

Thus, the steps for the preliminary pattern correcting work are inserted between step S0 and step S2 for accurately repairing the Levenson phase shift mask. If the preliminary pattern correcting work is not carried out, the Levenson phase shift mask is hardly rescued from the abnormal difference in transmittance and the abnormal phase difference by using the relations shown in FIGS. 9 to 11. However, the relations shown in FIGS. 9 to 11 are appropriate to the Levenson phase shift mask after the preliminary pattern correcting work, and the defective Levenson phase shift masks are repaired through steps S2, S3 and S1 as similar to those described in connection with the repairing method implementing the first embodiment.

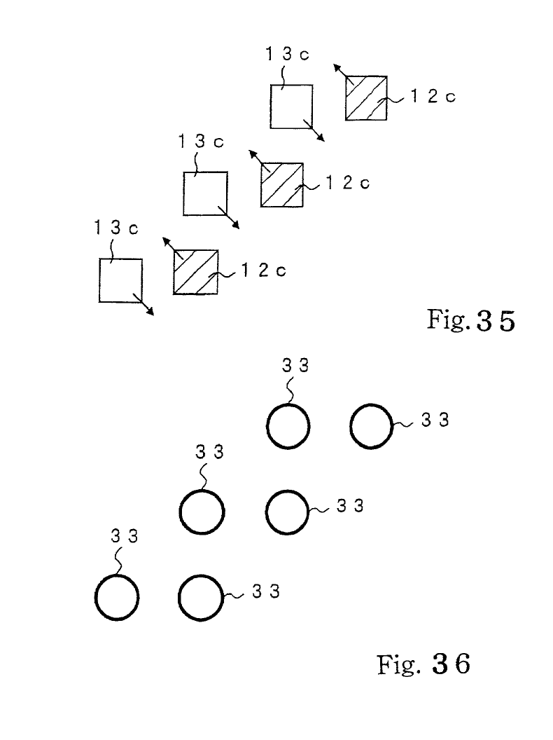

The preliminary pattern correcting work is preferable for other device pattern with thin/thick transparent portions arranged at irregular intervals. FIG. 35 shows another device pattern. The thin transparent portions for the phase shifter 12c are paired with the thick transparent portions for the non-phase shifter 13c, and the pairs of thin/thick transparent portions are obliquely arranged at 45 degrees with respect to the direction of rows. The thin transparent portions are arranged on a virtual oblique line, and the thick transparent portions are arranged on another virtual oblique line. The oblique lines are in parallel to each other. The thin/thick transparent portions occupy square areas, respectively.

The Levenson phase shift mask is installed in the mask simulator, and is radiated with the laser light beam. The transmitted light form optical images 32 of the thin/thick transparent portions on the CCD camera 6. The optical images of the thin/thick transparent portions are elliptical, and the major axes of the elliptical images are directed to the perpendicular directions to the virtual oblique lines, i.e., 45 degrees with respect to the directions of rows. Thus, the optical images 32 are elongated toward the vacant area, which is covered with the photo shield layer without any window.

Subsequently, the device pattern is corrected in such a manner that the space between the virtual oblique lines is narrows as shown in FIG. 35. The elliptical images become close to circular optical images. The above-described steps are repeated until circular optical images 33 are observed as shown in FIG. 36. When the circular optical images 33 are observed, the method proceeds to step S2 so as to check the phase shifter 12c and the non-phase shifter 13c to see whether or not the abnormal difference in transmittance and the abnormal phase difference take place. If the Levenson phase shift mask is defective due to the abnormal difference in transmittance or the abnormal phase difference, the Levenson phase shift mask is repaired in step S1.

As will be appreciated from the foregoing description, the method according to the present invention includes the step of analyzing the optical image of the three-dimensional device pattern between the phase shifter and the non-phase shifter and the step of correcting the device pattern by reshaping the thin/thick transparent portions. The three dimensional device pattern surely has the influences on the optical image, and the defects are eliminated from the Levenson phase shift mask by reshaping the three-dimensional device pattern. The analysis is carried out on the basis of the dispersion of light intensity taken by the image pick-up device such as a CCD camera. For this reason, the analysis does not consume a long time.

Although particular embodiments of the present invention have been shown and described, it will be apparent to those skilled in the art that various changes and modifications may be made without departing from the spirit and scope of the present invention.

For example, the present invention is applicable to any kind of three-dimensional photo mask. The method implementing the third embodiment may be applicable to a Levenson phase shift mask formed with the supplementary phase shifter and supplementary non-phase shifter as well as the phase shifter and non-phase shifter.

The mask may have more than two transparent portions different in three-dimensional configuration from one another.

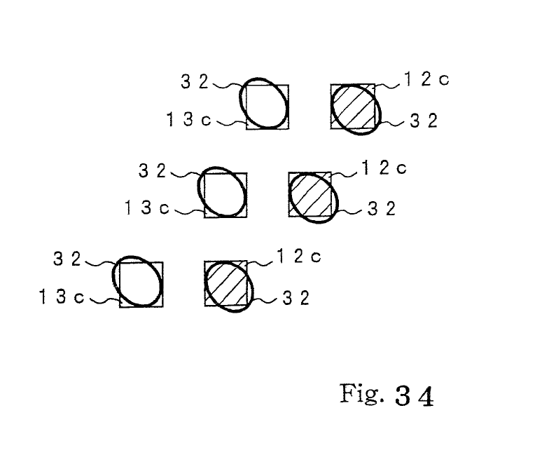

A double trench Levenson phase shift mask may have the pattern shown in FIG. 31 or 34. In this instance, the additional steps are required for the method according to the present invention.

What is claimed is:

1. A method for repairing a photo mask having a photo-shielded portion and plural transparent portions different in three-dimensional configuration from one another, comprising the steps of:
(a) radiating said photo mask with a light so as to obtain optical images each representative of said plural transparent portions at plural defocusing points, respectively;
(b) analyzing said optical images to see whether or not at least one optical property of said plural transparent portions is adjusted to a target value on the basis of a difference in measurement between said plural transparent portions on said optical images; and
(c) selectively reshaping said plural transparent portions for changing the three dimensional configurations thereof for adjusting said at least one optical property to said target value when the answer at said step (b) is given negative.

2. The method as set forth in claim 1, in which said plural transparent portions serve as a non-phase shifter transmitting a first part of said light and a phase shifter transmitting a second part of said light for introducing a phase difference between said first part and said second part so that said at least one optical property is said phase difference.

3. The method as set forth in claim 2, in which said phase difference is targeted at 180 degrees.

4. The method as set forth in claim 2, in which one of said plural transparent portions serving as said phase shifter is thinner than another of said plural transparent portions serving as said non-phase shifter.

5. The method as set forth in claim 2, in which said phase shifter is targeted for being equal in transmittance to said non-phase shifter so that said optical images are further analyzed to see whether or not the difference in said transmittance between said phase shifter and said non-phase shifter is adjusted to be zero in said step c).

6. The method as set forth in claim 5, in which the measurements on parts of said optical images representative of said phase shifter are either smaller or larger in value than the measurements on other parts of said optical images representative of said non-phase shifter at all of said defocusing points when said difference in transmittance is deviated from said target value.

7. The method as set forth in claim 5, in which the measurements on parts of said optical images representative of said phase shifter at said defocusing points are equal to the measurements on other parts of said optical images representative of said non-phase shifter at the defocusing points different from said defocusing points when said phase difference is deviated from the target value.

8. The method as set forth in claim 5, in which said phase shifter and said non-phase shifter are respectively implemented by transparent sub-portions of a transparent substrate defined by trenches and other transparent sub-portions of said transparent substrate defined without any trench so that said photo mask is categorized in a single trench Levenson phase shift mask.

9. The method as set forth in claim 8, in which said transparent sub-portions are alternated with said other transparent sub-portions at regular intervals in such a manner as to be arranged in rows and columns.

10. The method as set forth in claim 9, in which said transparent sub-portions and said other transparent sub-portions occupy square areas equal in size.

11. The method as set forth in claim 10, in which each of said square areas measures (0.15 micron±7.5 nanometers) by (0.15 micron±7.5 nanometers), and said square areas are arranged at regular pitches of (0.3 microns±15 nanometers).

12. The method as set forth in claim 8, in which said trenches are increased in area without changing the depth in said step (c) when said phase shifter is smaller in transmittance than said non-phase shifter.

13. The method as set forth in claim 8, in which said trenches are increased in depth without changing the area in said step (c) when said phase difference is decided to be deviated from said target value.

14. The method as set forth in claim 8, in which said transparent sub-portions and said other transparent sub-portions are altered at irregular intervals, and said photo shield portion is formed with narrow transparent sub-portions defined by trenches and other narrow transparent sub-portions defined without any trench in relatively long intervals in such a manner that each of said transparent sub-portions is adjacent to one of said other transparent sub-portions or one of said other narrow transparent sub-portions and that each of said other transparent sub-portions is adjacent to one of said transparent sub-portions or one of said narrow transparent sub-portions so that said transparent sub-portions, said other transparent sub-portions, said narrow transparent sub-portions defined with said trenches and said narrow transparent sub-portions defined without any trench are arranged at regular intervals.

15. The method as set forth in claim 14, in which said transparent sub-portions and said other transparent sub-portions occupy wide square areas equal in size, and said narrow transparent portions and said other narrow transparent sub-portions occupy narrow square areas equal in size.

16. The method as set forth in claim 15, in which each of said wide square areas and each of said narrow square areas respectively measure (0.15 micron ±7.5 nanometers) by (0.15 micron±7.5 nanometers) and (0.12 micron±6 nanometers) by (0.12 micron±6 nanometers), and said regular pitches are 0.3 micron.

17. The method as set forth in claim 5, in which said phase shifter and said non-phase shifter are respectively implemented by transparent sub-portions defined by deep trenches and other transparent sub-portions defined by shallow trenches so that said photo mask is categorized in a dual trench Levenson phase shift mask.

18. The method as set forth in claim 17, in which said transparent sub-portions are alternated with said other transparent sub-portions at regular intervals in such a manner as to be arranged in rows and columns.

19. The method as set forth in claim 18, in which said transparent sub-portions and said other transparent sub-portions occupy square areas equal in size.

20. The method as set forth in claim 19, in which each of said square areas measures (0.15 micron±7.5 nanometers) by (0.15 micron±7.5 nanometers), and said square areas are arranged at regular pitches of (0.3 microns±15 nanometers).

21. The method as set forth in claim 17, in which said deep trenches are increased in depth without changing the area thereof in said step (c) when said phase difference between said phase shifter and said non-phase shifter is deviated from 180 degrees.

22. The method as set forth in claim 17, in which said deep trenches and said shallow trenches are equally increased in depth without changing the area thereof in said step (c) when said difference in transmittance is deviated from zero.

23. The method as set forth in claim 22, in which the difference in depth is of the order of 250 nanometers when said step (c) is completed.

24. The method as set forth in claim 17, in which said transparent sub-portions and said other transparent sub-portions are altered at irregular intervals, and said photo shield portion is formed with narrow transparent sub-portions defined by trenches and other narrow transparent sub-portions defined without any trench in relatively long intervals in such a manner that each of said transparent sub-portions is adjacent to one of said other transparent sub-portions or one of said other narrow transparent sub-portions and that each of said other transparent sub-portions is adjacent to one of said transparent sub-portions or one of said narrow transparent sub-portions so that said transparent sub-portions, said other transparent sub-portions, said narrow transparent sub-portions defined with said trenches and said narrow transparent sub-portions defined without any trench are arranged at regular intervals.

25. The method as set forth in claim 24, in which said transparent sub-portions and said other transparent sub-portions occupy wide square areas equal in size, and said narrow transparent portions and said other narrow transparent sub-portions occupy narrow square areas equal in size.

26. The method as set forth in claim 25, in which each of said wide square areas and each of said narrow square areas respectively measure (0.15 micron±7.5 nanometers) by (0.15 micron±7.5 nanometers) and (0.12 micron±6 nanometers) by (0.12 micron±6 nanometers), and said regular pitches are 0.3 micron.

27. The method as set forth in claim 17, in which said deep trenches are twice deeper than said shallow trenches.

28. The method as set forth in claim 8, in which said transparent sub-portions and said other transparent sub-portions occupy square areas equal in size and arranged at selected lattice points in a virtual lattice imaged on said photo mask, and said method further comprises the step of (d) reshaping said transparent sub-portions and said other transparent sub-portions in such a manner that rays passing through said transparent sub-portions and said other transparent sub-portions form an optical image consisting of plural circles before said step (a).

29. The method as set forth in claim 28, in which said step (d) includes the sub-steps of
d-1) radiating said photo mask with said light so that said rays reaches an image forming plane through said transparent sub-portions and said other transparent sub-portions,
d-2) checking said optical image on said image forming plane to see whether or not said rays form elliptical images,
d-3) reshaping said transparent sub-portions and said other transparent sub-portions when the answer at said sub-step d-2) is given negative, and
d-4) repeating said sub-steps d-1), d-2) and d-3) until said rays form the circular images on said image forming plane.

30. The method as set forth in claim 1, in which said optical images are formed on a photo-electric converting plane of a charge-coupled device.
